(19) United States
(12) Patent Application Publication
(10) Pub. No.: US 2015/0206866 A1
(43) Pub. Date: Jul. 23, 2015

(54) Semiconductor Package and Methods of Forming Same

(71) Applicant: Taiwan Semiconductor Manufacturing Company, Ltd., Hsin-Chu (TW)

(72) Inventors: Chen-Hua Yu, Hsin-Chu (TW); Kuo-Chung Yee, Taoyuan City (TW); Mirng-Ji Lii, Sinpu Township (TW); Chien-Hsun Lee, Chu-tung Town (TW); Jiun Yi Wu, Zhongli City (TW)

(73) Assignee: Taiwan Semiconductor Manufacturing Company, Ltd., Hsin-Chu (TW)

(21) Appl. No.: 14/252,261

(22) Filed: Apr. 14, 2014

Related U.S. Application Data
(60) Provisional application No. 61/928,812, filed on Jan. 17, 2014.

(51) Int. Cl. H01L 25/18; H01L 23/48; H01L 23/31; H01L 21/56; H01L 25/00; H01L 23/00

(52) U.S. Cl. CPC H01L 25/18; H01L 25/50; H01L 24/17; H01L 24/81; H01L 23/3107; H01L 21/565; H01L 23/481; H01L 2924/1431; H01L 2924/1436; H01L 2924/15311; H01L 2924/15321; H01L 2924/15331; H01L 2224/13147; H01L 2224/13144; H01L 2224/13139

(57) ABSTRACT

An embodiment package-on-package (PoP) device includes a fan-out structure, one or more memory chips, and a plurality of connectors bonding the one or more memory chips to the fan-out structure. The fan-out structure includes a logic chip, a molding compound encircling the logic chip, and a plurality of conductive pillars extending through the molding compound.

### PRIORITY CLAIM AND CROSS-REFERENCE

This application claims the benefit of U.S. Provisional Application No. 61/928,812, filed on Jan. 17, 2014, entitled “Semiconductor Package and Methods of Forming Same,” which application is hereby incorporated herein by reference.

### BACKGROUND

3D package applications such as package-on-package (PoP) are becoming increasingly popular and widely used in mobile devices because they can enhance electrical performance by increasing bandwidth and shortening routing distance between logic chips (e.g., application processors) and memory chips, for instance. However, with the advent of wide input/output (wide IO) memory chips, higher speed and lower power requirements, package body size, and the number of package layers requirements are increasing. Larger and thicker devices and the physical dimensions electrical performances are becoming constrained. Existing PoP devices are challenged to meet fine channels and high density routing requirements using conventional ball joint packages due to yield loss at the ball joint. Improved devices and methods of manufacturing the same are required.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 11A illustrate cross-sectional views of various intermediate stages of manufacturing a PoP device in accordance with some embodiments;

FIG. 11B illustrates a cross-sectional view of a PoP device in accordance with an alternative embodiment;

FIGS. 12 through 16A illustrate cross-sectional views of various intermediate stages of manufacturing a PoP device in accordance with some alternative embodiments; and

FIG. 16B illustrates a cross-sectional view of a PoP device in accordance with another alternative embodiment.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments include PoP devices having logic and memory chips. Interconnections between the logic and memory chips may be done using fan-out, chip-on-chip, and chip-on-substrate structures. For example, one or more chips may be encircled by molding compounds, and interconnect structures are formed in the molding compounds. Thus, I/O pads of each chip may be distributed to a larger surface area than the chip itself, allowing for various advantages over existing PoP devices. For example, various embodiments can meet system in package (SiP) fine ball pitch requirements for interconnecting logic chips (e.g., application processors (AP)) with wide IO memory stacking. Other advantageous features may include improved speed and power consumption, lower manufacturing costs, increased capacity, improved yield, thinner form factors, improved level 2 reliability margins, and the like.

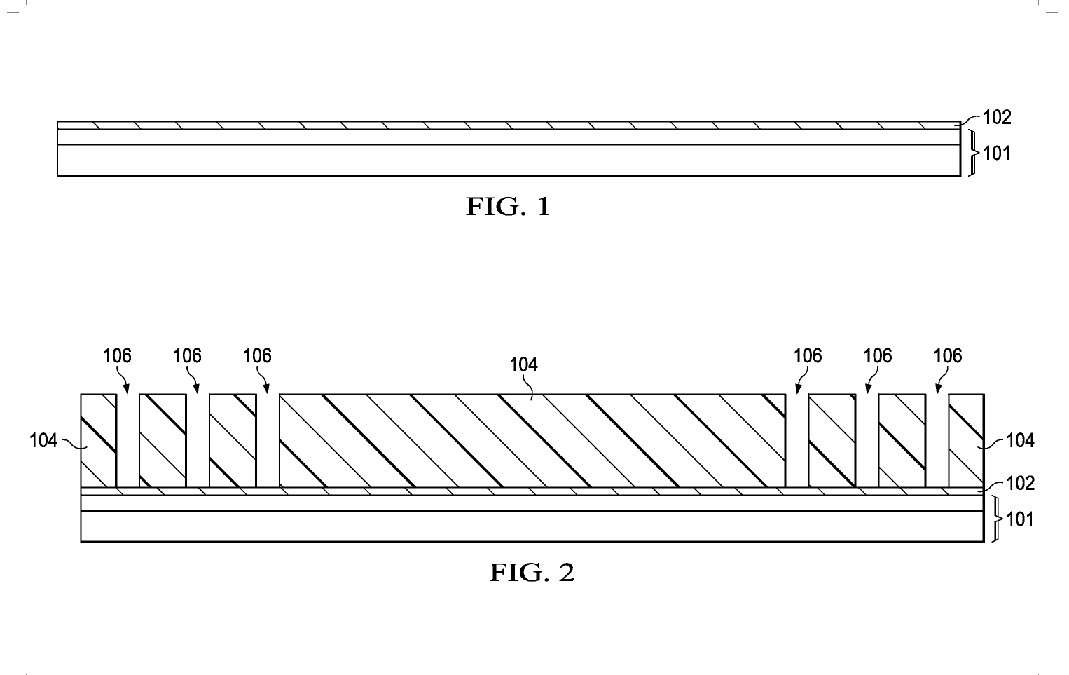

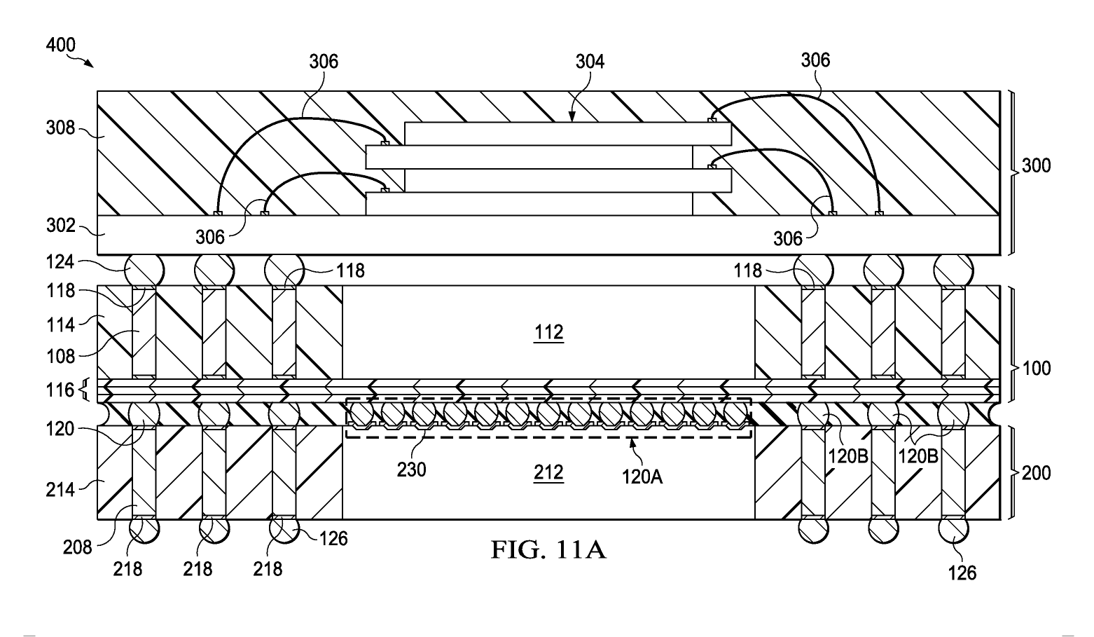

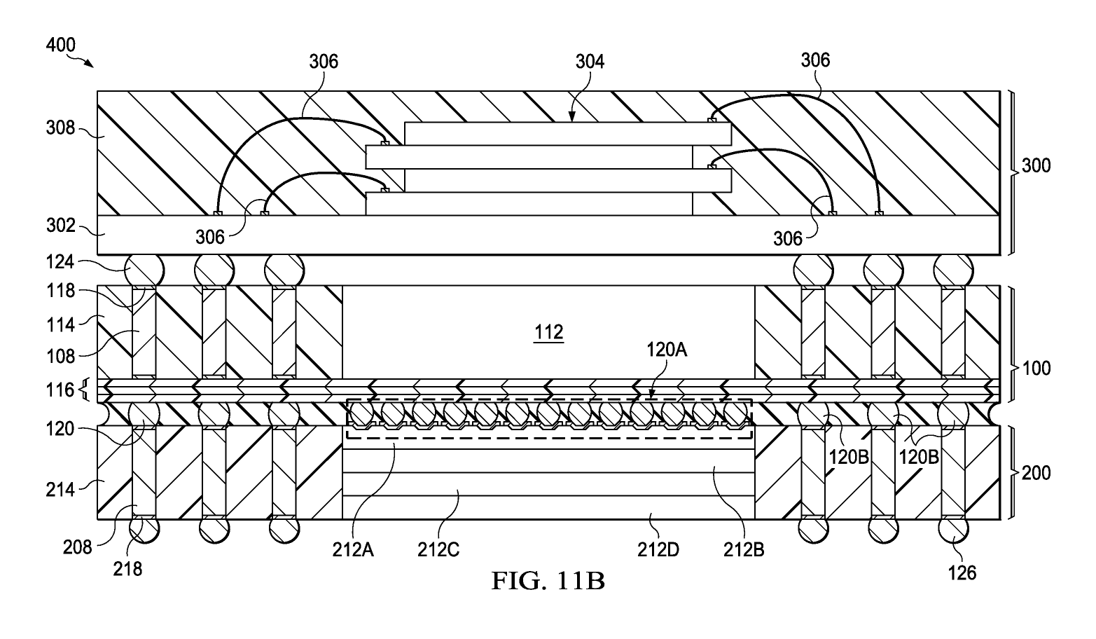

FIGS. 1 through 11A illustrate cross-sectional views of various intermediate stages of manufacturing a PoP device 400 (see FIG. 11A) in accordance with some embodiments. FIG. 1 illustrates a cross sectional view of a carrier 101. Carrier 101 may be a glass carrier or the like. A conductive seed layer 102 may be disposed over carrier 101, for example, using a sputtering process. Seed layer 102 may be formed of a conductive material such as copper, silver, gold, and the like.

FIGS. 2 through 4 illustrate the formation of conductive pillars over carrier 101. As illustrated by FIG. 2, a patterned photoresist 104 may be formed over seed layer 102 and carrier 101. For example, photoresist 104 may be deposited as a blanket layer over seed layer 102. Next, portions of photoresist 104 may be exposed using a photo mask. Exposed or unexposed portions of photoresist 104 are then removed depending on whether a negative or positive resist is used. The resulting patterned photoresist 104 may include openings 106, which may be disposed at peripheral areas of carrier 101.

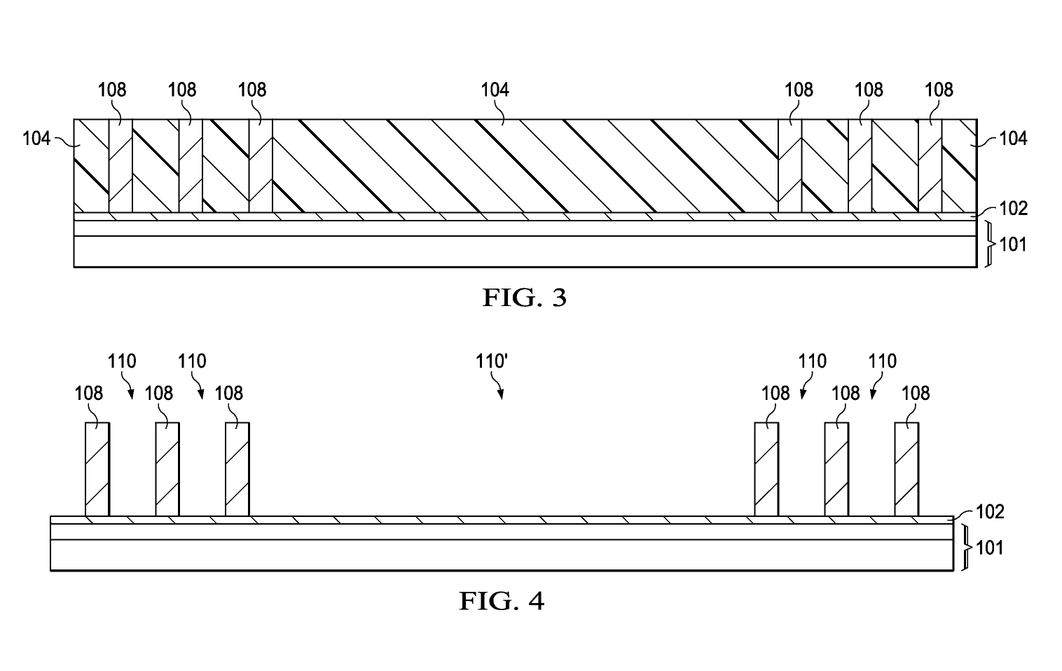

FIG. 3 illustrates the filling of openings 106 with a conductive material such as copper, silver, gold, and the like to form conductive pillars 108. The filling of openings 106 may include first depositing a seed layer (not shown) and electro-chemically plating openings 106 with a conductive material. The conductive material may overfill openings 106, and a chemical mechanical polish (CMP) may be performed to remove excess portions of the conductive material over photoresist 104. Next, as illustrated by FIG. 4, photoresist 104 is removed, for example, in an ashing process.

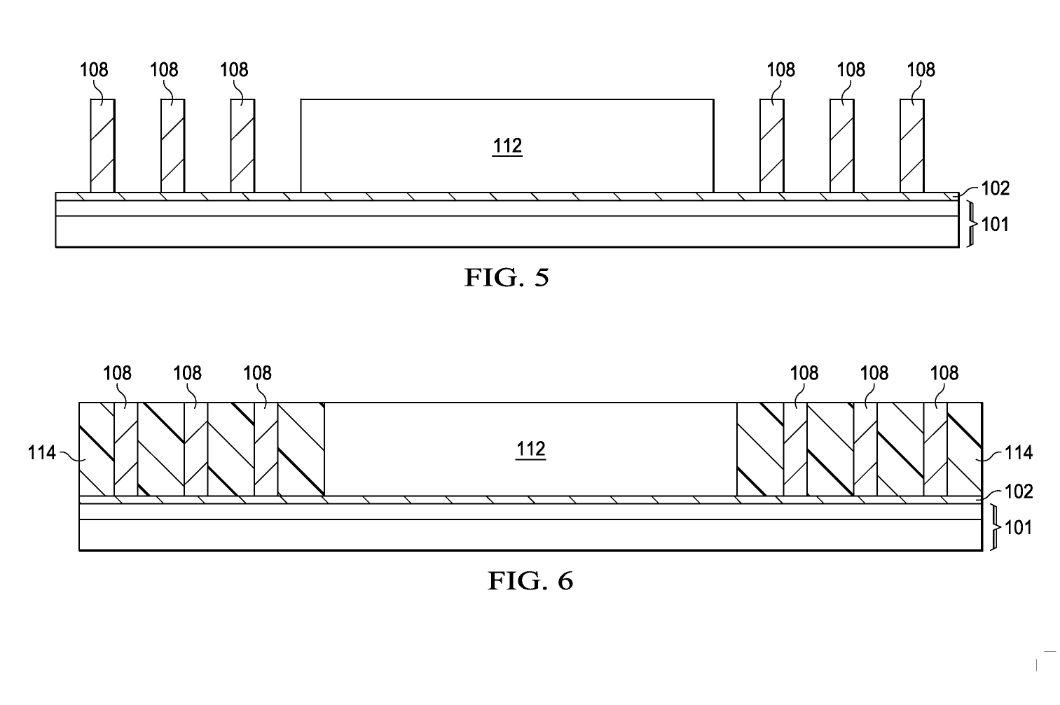

Thus, conductive pillars 108 are formed over seed layer 102. Alternatively, conductive pillars 108 may be replaced with conductive studs or conductive wires (e.g., copper, gold, or silver wire). Conductive pillars 108 may be spaced apart from each other by openings 110. At least one opening 110′ between adjacent conductive pillars 108 may be large enough to dispose a semiconductor chip (e.g., a logic chip 112, see FIG. 5) therein. In some example embodiments, conductive pillars 108 may have a pitch of about 100 μm to about 500 μm.

FIG. 5 illustrates the disposition of a semiconductor chip (e.g., logic chip 112) over carrier 101. Logic chip 112 may be an application processor (AP), although other kinds of semiconductor chips (e.g., memory chips) may be used as well. In some example embodiments, logic chip 112 may have a thickness of about 40 μm to 300 μm. Lateral surfaces of logic chip 112 and conductive pillars 108 may be substantially level. This may be achieved, for example, by selecting an appropriate height of photoresist 104 and/or performing a CMP on conductive pillars 108 to a desired height matching logic chip 112. Logic chip 112 may be attached to carrier 101 using an adhesive layer, for example.

Next, as illustrated by FIG. 6, molding compound 114 is dispensed to fill gaps between conductive pillars 108 and logic chip 112. Molding compound 114 may include any suitable material such as an epoxy resin, a molding underfill, and the like. Suitable methods for forming molding compound 114 may include compressive molding, transfer molding, liquid encapsulent molding, and the like. For example, molding compound 114 may be dispensed between conductive pillars 108/logic chip 112 in liquid form. Subsequently, a curing process is performed to solidify molding compound 114. The filling of molding compound 114 may overflow conductive pillars 108/logic chip 112 so that molding compound 114 covers top surfaces of conductive pillars 108/logic chip 112. A CMP (or other grinding/etch back technique) may be performed to expose top surfaces of conductive pillars 108/logic chip 112. In the resulting structure, lateral surfaces of molding compound 114, conductive pillars 108, and logic chip 112 may be substantially level. Furthermore, conductive pillars 108 may extend through molding compound 114, and thus, conductive pillars 108 may also be referred to as through-molding vias (TMVs) 108. In a top-down view (not shown), molding compound 114 may encircle logic chip 112.

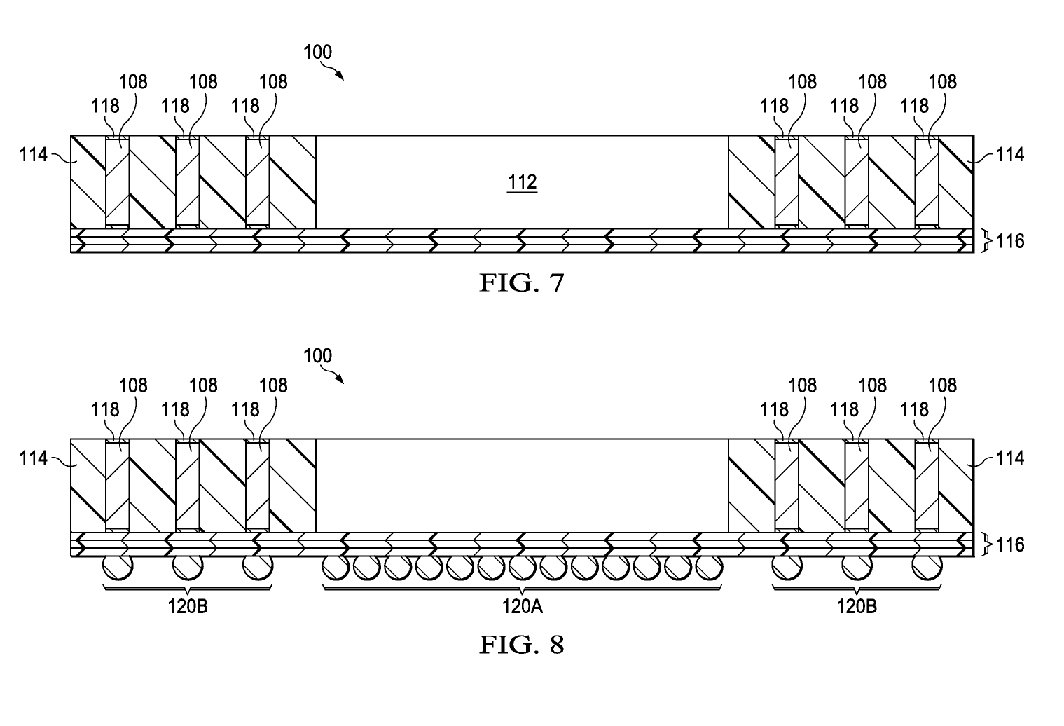

Interconnect structures such as one or more redistribution layers (RDLs) 116 may be formed on logic chip and molding compound 114. Contact pads 118 may also be formed on conductive pillars 108. The resulting fan-out structure 100 is illustrated in FIG. 7. Fan-out structure 100 includes logic chip 112, conductive pillars 108, molding compound 114, and RDLs 116. RDLs 116 may extend laterally past edges of logic chip 112 over molding compound 114 and conductive pillars 108. RDLs 116 may include interconnect structures (e.g, conductive lines and/or vias) formed in one or more polymer layers. Polymer layers may be formed of any suitable material (e.g., polyimide (PI), polybenzoxazole (PBO), benzocyclobuten (BCB), epoxy, silicone, acrylates, nano-filled pheno resin, siloxane, a fluorinated polymer, polynorbornene, and the like) using any suitable method, such as, a spin-on coating technique, and the like. The polymer layers may be formed over logic chip 112 while logic chip 112 is still attached to carrier 101 (not illustrated in FIG. 7).

The interconnect structures of RDLs 116 may be formed in the polymer layers and electrically connect to logic chip 112 and/or conductive pillars 108. The formation of the interconnect structures may include patterning the polymer layers (e.g., using a combination of photolithography and etching processes) and forming the interconnect structures (e.g., depositing a seed layer and using a mask layer to define the shape of the interconnect structures) in the patterned polymer layers. After RDLs 116 are formed, fan-out structure 100 may be removed from carrier 101, and the orientation of fan-out structure 100 may be flipped as illustrated in FIG. 7.

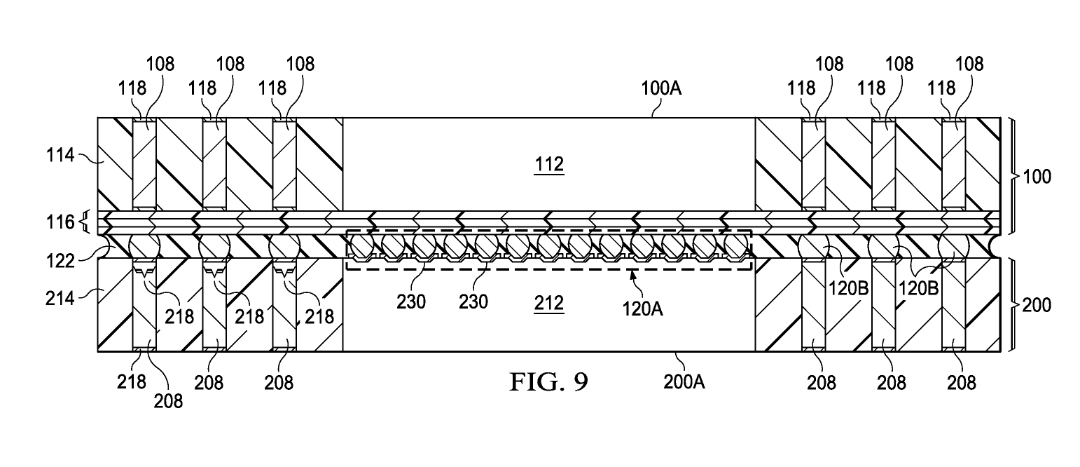

FIG. 8 shows the formation of connectors 120 (labeled 120A and 120B) on RDLs 116 in fan-out structure 100. Connectors 120 provide electrical connection to logic chip 112 and/or conductive pillars 108 through RDLs 116. Connectors 120 may or may not be uniform in dimension/distribution. For example, connectors 120A may be microbumps (μbumps) having a pitch of about 30 μm to about 100 μm, whereas connectors 120B may be control collapse chip connection (C4) bumps having a pitch of about 100 μm to about 500 μm. Differently sized connectors 120 allow for electrical connections to different electrical features in subsequently process steps (e.g., see FIG. 9). In such embodiments, connectors 120A may be formed on RDLs 116 prior to the formation of connectors 120B. In some embodiments, connectors 120 may have a height of about 30 μm to about 100 μm.

FIG. 9 illustrates fan-out structure 100 being bonded to another fan-out structure 200 using connectors 120. An underfill 122 may be dispensed between fan-out structures 100 and 200 around connectors 120. Underfill 122 may provide support for connectors 120.

Fan-out structure 200 may be substantially similar (both in structure and formation process) to fan-out structure 100, where similar reference numerals indicate like elements. For example, fan-out structure 200 includes a semiconductor chip (e.g., memory chip 212) and conductive pillars 208. Memory chip 212 may be a wide input/output (I/O) memory chip (e.g., having a thousand or more contact pads 230), although other kinds of semiconductor chips (e.g., other types of memory chips) may be used as well. In some embodiments, memory chip 212 may have a thickness of about 40 μm to about 300 μm.

Memory chip 212 and conductive pillars 208 may be held together by molding compound 214, and lateral surfaces of memory chip 212, conductive pillars 208, and molding compound 214 may be substantially level. Fan-out structure 200 may not include any RDLs, and connectors 120 may be bonded to fan-out structure 200 by electrically connecting to contact pads on conductive pillars 208 and memory chip 212. For example, connectors 120A may be electrically connected to contact pads 230 on memory chip 212, and connectors 120B may be electrically connected to contact pads 218 on conductive pillars 208. Pitches of connectors 120A and 120B may be selected to correspond with respective pitches of contact pads 230 and 218, respectively.

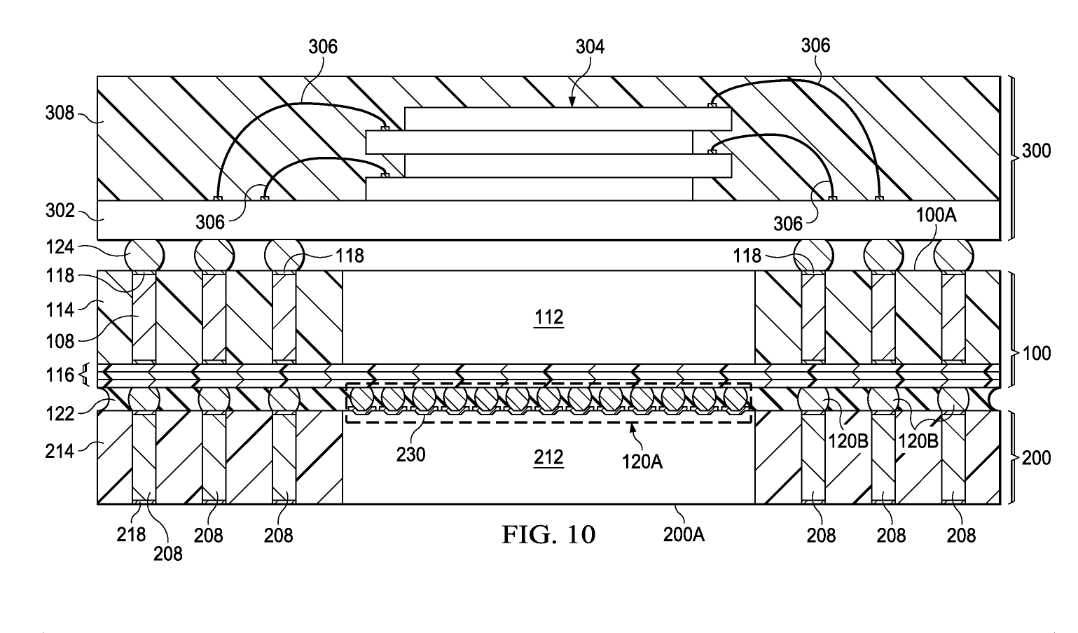

Additional packaging components may be optionally bonded to fan-out structures 100 and 200. For example, integrated package (IC) package structure 300 may be bonded to an opposing surface of fan-out structure 100 as fan-out structure 200. The resulting structure is illustrated in FIG. 10. Package structure 300 may be a memory package, such as a low-power double data rate 2 (LP-DDR2) package, LP-DDR3 package, LP-DDRₓ package, wide IO package, and the like. Package structure 300 may include a plurality of stacked memory dies (e.g., dynamic random access memory (DRAM) dies 304) bonded to a package substrate 302, for example, using wire bonds 306. DRAM dies 304 and wire bonds 306 may be encased by a protective molding compound 308. Other types of package structures may be used as well. Alternatively, package structure 300 may be omitted depending on package design.

Package substrate 302 may be an organic substrate or a ceramic substrate and may include interconnect structures (e.g., conductive lines and/or vias) that provide electrical connections to various DRAM dies 304. Connectors 124 may be disposed on a bottom surface of package substrate 302. Package structure 300 may be bonded to fan-out structure 100 using connectors 124, which may be bonded to contact pads 118 on conductive pillars 108. Logic chip 112 may be electrically connected to DRAM dies 304 through RDLs 116, conductive pillars 108, connectors 124, substrate 302, and wire bonds 306. Thus, by including conductive pillars 108 in fan-out structure 100, additional package structures may be bonded to fan-out structure 100 that are electrically connected to logic chip 112.

FIG. 11A illustrates the formation of connectors 126 (e.g., ball grid array (BGA) balls) on a surface of fan-out structure 200 opposing fan-out structure 100. Thus, PoP device 400 is completed. Connectors 126 are formed on contact pads 218 to electrically connect to conductive pillars 208. In some embodiments, connectors 126 have a pitch of about 250 μm to about 500 μm. Connectors 126 may be used to electrically connect PoP device 400 to a motherboard (not shown) or another device component of an electrical system. Conductive pillars 208 (along with other interconnect structures of PoP device 400) provide electrical connection between connectors 126 and logic chip 112, memory chip 212, and/or DRAM dies 304.

PoP device 400 includes two fan-out structures 100 and 200, which are electrically connected to each other through connectors 120 and RDLs 116. Conductive pillars 108 and 208 in fan-out structures 100 and 200, respectively, may further provide electrical connections to additional package components (e.g., package structure 300 and/or a mother board). Thus, logic (e.g., AP) and memory (e.g., wide IO) chips may be bonded using fan-out structures (e.g., molding compounds, conductive pillars, and RDLs). Advantageous features of PoP device 400 may include one or more of: cost effectiveness (e.g., due to the use of relatively simple interconnect structures without expensive through-substrate vias), increased capacity (e.g., due to the ability to include wide IO chips with other memory chips), improved reliability of electrical connections, improved yield, higher electrical speed (e.g., due to shorter routing distances between logic chip 112 and memory chips 212 and 304), thinner form factors, good level 2 reliability margins (e.g., improved results in temperature cycle (TC) and/or drop tests), and the like.

FIG. 11B illustrates a cross-sectional view of PoP device 400 in accordance with alternative embodiments. In FIG. 11B, fan-out structure 200 may include multiple stacked semiconductor chips, such as, memory chips 212A through 212D, which may be wide IO chips. Each memory chip 212A through 212D may have a thickness of about 40 μm to about 300 μm. Although four memory chips are illustrated, any number of memory chips may be used depending on package design. The stacked semiconductor chips may be interconnected through connectors (not shown) disposed between each memory chip 212A through 212D. Fan-out structure 100 may be bonded to stacked memory chips 212A through 212D through contact pads on a top surface of top-most memory chip 212A. Thus, additional wide IO chips may be included in PoP device 400 using a similar package configuration.

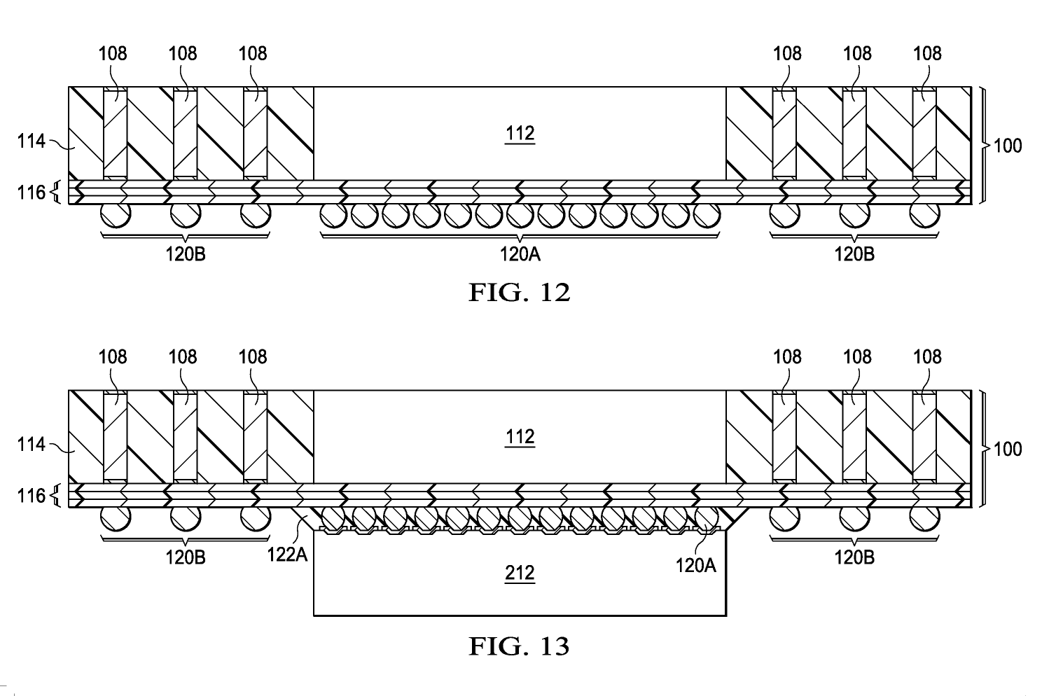

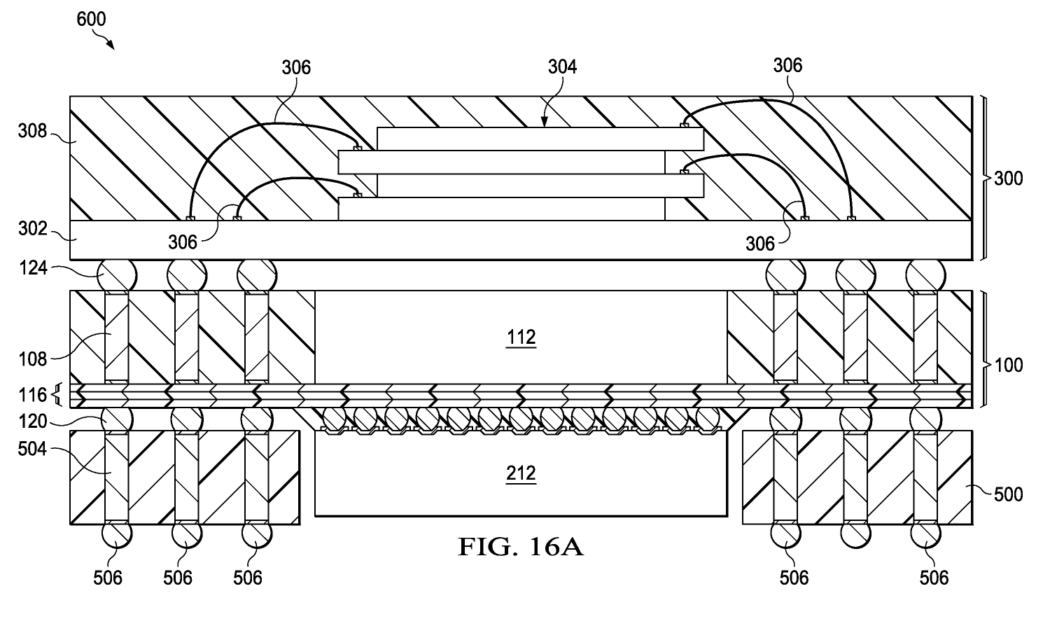

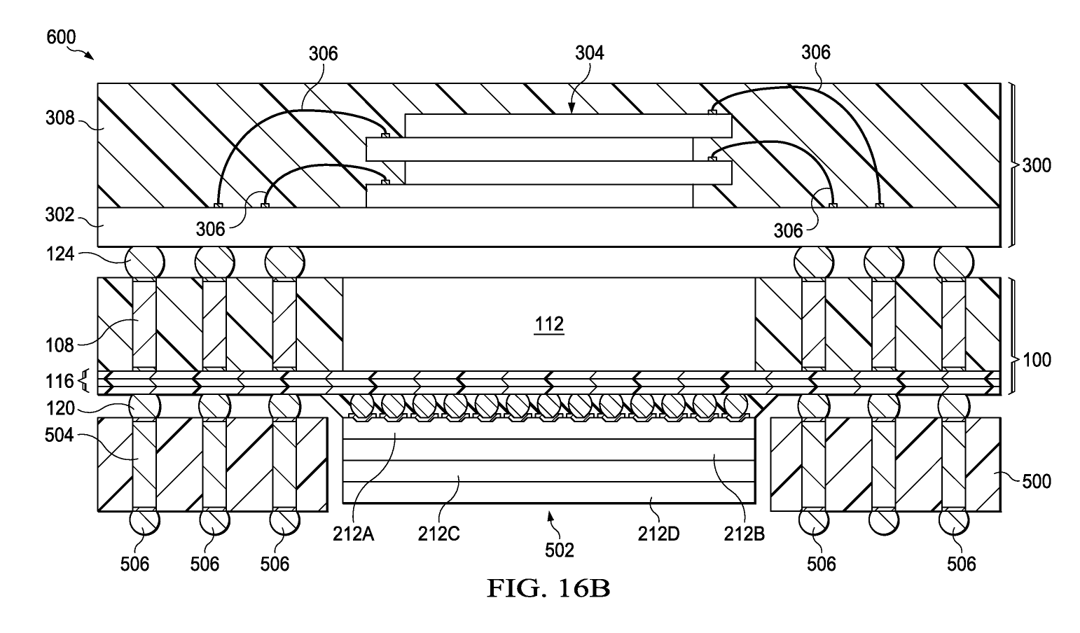

FIGS. 12 through 16A illustrate cross-sectional views of various intermediate stages of manufacturing a PoP device 600 (see FIG. 16A) in accordance with some alternative embodiments. FIG. 12 illustrates a cross-sectional view of fan-out structure 100. Fan-out structure 100 in FIG. 12 may be substantially similar to fan-out structure 100 illustrated in FIG. 8, where like reference numbers indicate like elements. Next, as illustrated by FIG. 13, a semiconductor chip, such as memory chip 212 (e.g., a wide IO chip) is bonded to fan-out structure 100. Unlike PoP device 400, memory chip 212 may not be part of a separate fan-out structure 200. Memory chip 212 may be bonded to fan-out structure 100 using connectors 120A. Molding compound 122A may be dispensed between connectors 120A. RDLs 116 may provide electrical connection between memory chip 212 and logic chip 112/conductive pillars 108.

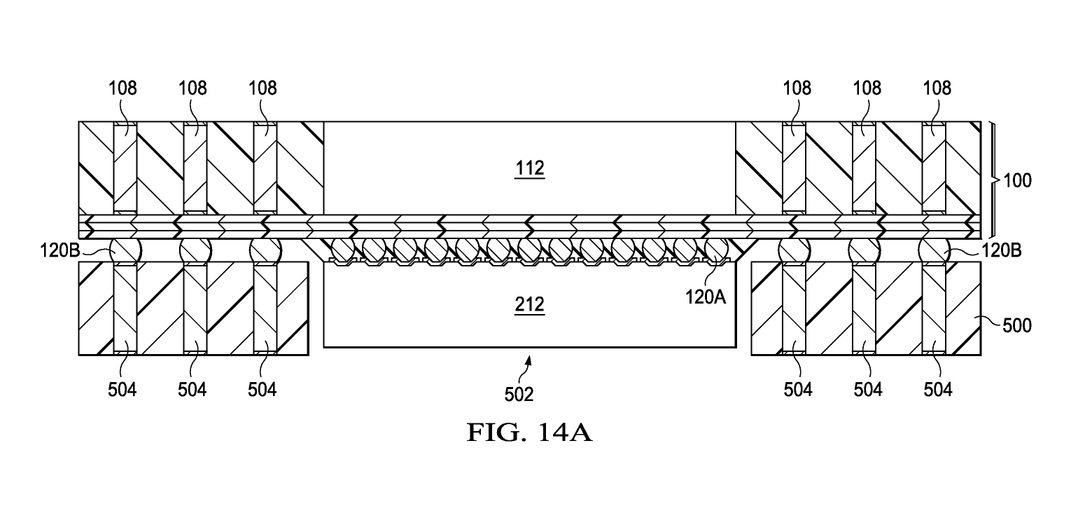

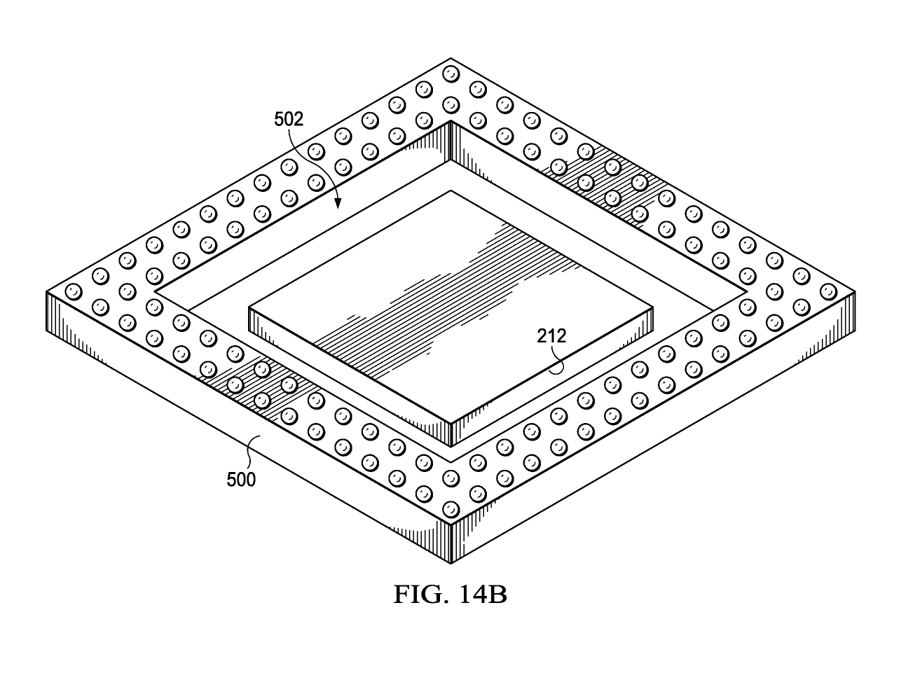

FIG. 14A illustrates the bonding of fan-out structure 100 to a package substrate 500. Package substrate 500 may be a printed circuit board, an interposer, or the like, and package substrate 500 may include conductive interconnect structures 504, which may be electrically connected to connectors 120B. In some embodiments, package substrate 500 may have a thickness of about 50 μm to about 1,300 μm.

Package substrate 500 further includes a through-hole 502, and memory chip 212 may be at least partially disposed in through-hole 502. In a top-down view of package substrate 500 shown in FIG. 14B, package substrate 500 may encircle memory chip 212. In some embodiments, through-hole 502 may be formed by laser drilling package substrate 500. Thus, both package substrate 500 and memory chip 212 may be disposed on a same side of fan-out structure 100.

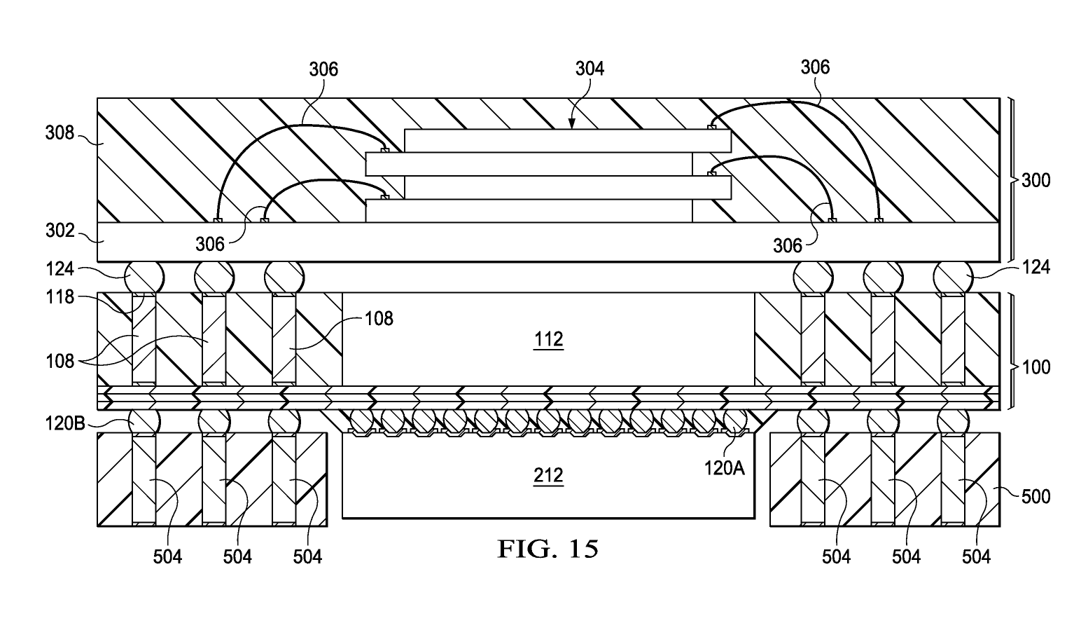

FIG. 15 illustrates the optional bonding of additional packaging components to fan-out structures 100. For example, package structure 300 may be bonded to an opposing surface of fan-out structure 100 as memory chip 212. Package structure 300 may be a memory package, such as a LP-DDR2 package, LP-DDR3 package, and the like. Package structure 300 may include a plurality of stacked memory dies (e.g., DRAM dies 304) bonded to a package substrate 302, for example, using wire bonds 306. DRAM dies 304 and wire bonds 306 may be encased by a protective molding compound 308. Other types of package structures may be used as well. Alternatively, package structure 300 may be omitted depending on package design.

Connectors 124 may be disposed on a bottom surface of package substrate 302. Package structure 300 may be bonded to fan-out structure 100 using connectors 124, which may be bonded to contact pads on conductive pillars 108. Logic chip 112 may be electrically connected to DRAM dies 304 through RDLs 116, conductive pillars 108, connectors 124, and substrate 302.

FIG. 16A illustrates the formation of connectors 126 (e.g., BGA balls) on a surface of package substrate 500 opposite fan-out structure 100. Thus, PoP device 600 is completed. In some embodiments, connectors 126 have a pitch of about 250 μm to about 500 μm. Connectors 126 may be used to electrically connect PoP device 600 to a motherboard (not shown) or another device component of an electrical system. Interconnect structures in package substrate 500, RDLs 116, conductive pillars 108, and various connectors 120 and 124 provide electrical connection between connectors 126 and logic chip 112, memory chip 212, and/or package structure 300.

PoP device 600 includes a fan-out structure 100 bonded to a package substrate 500/memory chip 212. Fan-out structure 100 is electrically connected to memory chip 212 and package substrate 500 through connectors 120 and RDLs 116. Conductive pillars 108 in fan-out structure 100 may further provide electrical connections to additional package components (e.g., package structure 300 and/or a mother board). Thus, logic (e.g., AP) and memory (e.g., wide IO) chips may be bonded using fan-out structures (e.g., having molding compounds, conductive pillars, and/or RDLs). Advantageous features of PoP device 600 may include one or more of: cost effectiveness (e.g., due to the use of relatively simple interconnect structures without expensive through-substrate vias), increased capacity (e.g., due to the ability to include wide IO chips with other memory chips), improved reliability of electrical connections, improved yield, higher electrical speed (e.g., due to shorter routing between logic chip 112 and memory chips 212 and 304), thinner form factors, good level 2 reliability margins (e.g., improved results in TC/drop tests), and the like.

FIG. 16B illustrates a cross-sectional view of PoP device 600 in accordance with alternative embodiments. In FIG. 16B, PoP device 600 may include multiple stacked semiconductor chips, such as, memory chips 212A through 212D, which may be wide IO chips. Although four memory chips are illustrated, any number of memory chips may be used depending on package design. The stacked memory chips may be interconnected through connectors disposed between each memory chip 212A through 212D. Fan-out structure 100 may be bonded to the memory chip stack through contact pads on a top surface of top-most memory chip 212A. Thus, additional wide IO chips may be included in PoP device 600 using a similar package configuration

Thus, as detailed above, various embodiment PoP devices having logic and memory chips may be bonded using fan-out structures. For example, a first fan-out structure may include a logic chip encircled by molding compounds. Interconnect structures (e.g., conductive pillars) may extend through the molding compound. Various memory chips (e.g., wide IO chips, LP-DDR2/DP-DDR3 chips, and the like) may be bonded to either side of the first fan out structure, and the RDLs and interconnect structure electrically connect the memory chips to the logic chip. The memory chips may be disposed in a second fan-out structure, directly bonded to the first fan-out structure, provided in another package structure, and the like. Advantages of various embodiments may include improved speed and power consumption, lower manufacturing costs, increased capacity, improved yield, thinner form factors, improved level 2 reliability margins, and the like.

In accordance with an embodiment, a package-on-package device includes a first fan-out structure, a second fan-out structure, and a plurality of connectors bonding the first fan-out structure to the second fan-out structure. The first fan-out structure includes a logic chip, a first molding compound encircling the logic chip, and a first plurality of conductive pillars extending through the first molding compound. The second fan-out structure includes one or more memory chips, a second molding compound encircling the one or more memory chips, and a second plurality of conductive pillars extending through the second molding compound.

In accordance with another embodiment, a package-on-package device includes a fan-out structure, one or more memory chips bonded to a surface of the fan-out structure, and a package substrate bonded to the surface of the fan-out structure. The fan-out structure includes a logic chip, a molding compound encircling the logic chip, and a plurality of through molding vias (TMVs) extending through the molding compound. The package substrate includes a through hole, and the one or more memory chips are disposed in the through hole.

In accordance with yet another embodiment, a method for forming a package on package device includes forming a fan-out structure and bonding one or more wide input/output (IO) chips to the fan out structure. The one or more wide IO chips is electrically connected to the logic chip. The method of forming the fan-out structure includes patterning a first plurality of openings in a photoresist layer over a carrier, filling the first plurality of openings with a conductive material to form a plurality of conductive pillars, and removing the photoresist layer leaving a second plurality of openings between each of the plurality of conductive pillars. The method of forming the fan-out structure further includes disposing a logic chip over the carrier in one of the second plurality of openings, and filling the second plurality of openings with a molding compound. Lateral surfaces of the molding compound and the logic chip are substantially level.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package-on-package (PoP) device comprising:
a first fan-out structure comprising:
a logic chip;
a first molding compound encircling the logic chip; and
a first plurality of conductive pillars extending through the first molding compound;
a second fan-out structure comprising:
one or more memory chips;
a second molding compound encircling the one or more memory chips; and
a second plurality of conductive pillars extending through the second molding compound; and
a first plurality of connectors bonding the first fan-out structure to the second fan-out structure.

2. The PoP device of claim 1, wherein the first fan out structure further comprises one or more redistribution layers (RDLs) electrically connecting the second fan-out structure to the logic chip and the first plurality of conductive pillars.

3. The PoP device of claim 1, further comprising a package structure bonded to a surface of the first fan-out structure opposing the second fan-out structure.

4. The PoP device of claim 3, wherein the package structure comprises:
a plurality of stacked dynamic random access memory (DRAM) chips;
a package substrate electrically connected to the plurality of stacked DRAM chips; and
a second plurality of connectors electrically connecting the package substrate to the first fan-out structure, wherein the second plurality of connectors is aligned with the first plurality of conductive pillars.

5. The PoP device of claim 1, wherein lateral surfaces of the logic chip, the first molding compound, and the first plurality of conductive pillars are substantially level, and wherein lateral surfaces of the one or more memory chips, the second molding compound, and the second plurality of conductive pillars are substantially level.

6. The PoP device of claim 1, further comprising a plurality of ball grid array (BGA) balls electrically connected to the second plurality of conductive pillars, wherein the plurality of BGA balls are disposed on a surface of the second fan-out structure opposing the first fan-out structure.

7. The PoP device of claim 1, wherein the logic chip is an application processor, and wherein the one or more memory chips include one or more wide input/output (IO) chips.

8. The PoP device of claim 1, wherein the first and the second pluralities of conductive pillars comprise copper, silver, gold, or a combination thereof.

9. A package-on-package (PoP) device comprising:
a fan-out structure comprising:
a logic chip;
a molding compound encircling the logic chip; and
a plurality of through molding vias (TMVs) extending through the molding compound;
one or more memory chips bonded to a first surface of the fan-out structure; and
a first package substrate bonded to the first surface of the fan-out structure, wherein the first package substrate comprises a through hole, and wherein the one or more memory chips are disposed in the through hole.

10. The PoP device of claim 9, wherein the fan-out structure further comprises one or more redistribution layers (RDLs) on the logic chip and the molding compound, wherein the one or more RDLs electrically connect the one or more memory chips and the package substrate to the logic chip and the plurality of TMVs.

11. The PoP device of claim 9, further comprising a package structure bonded to a second surface of the fan-out structure opposing the first surface of the fan-out structure, wherein the package structure is a low-power double data rate 2 (LP-DDR2) package or a LP-DDR3 package.

12. The PoP device of claim 9, wherein the logic chip is an application processor, and wherein the one or more memory chips include one or more wide input/output (IO) chips.

13. The PoP device of claim 9, further comprising a plurality of ball grid array (BGA) balls disposed on a surface of the first package substrate opposite the fan-out structure, wherein interconnect structures in the first package substrate electrically connect the plurality of BGA balls to the fan-out structure.

14. The PoP device of claim 9, wherein the first package substrate is an organic substrate or a ceramic substrate.

15. The PoP device of claim 9, wherein the plurality of TMVs comprise copper, silver, gold, or a combination thereof.

16. A method for forming a package-on-package (PoP) device comprising:
forming a first fan-out structure, wherein forming the first fan-out structure comprises:
patterning a first plurality of openings in a photoresist layer over a carrier;
filling the first plurality of openings with a conductive material to form a plurality of conductive pillars;
removing the photoresist layer leaving a second plurality of openings between each of the plurality of conductive pillars;
disposing a logic chip over the carrier in one of the second plurality of openings; and
filling the second plurality of openings with a molding compound, wherein lateral surfaces of the molding compound and the logic chip are substantially level; and
bonding one or more wide input/output (IO) chips to the first fan out structure, wherein the one or more wide IO chips is electrically connected to the logic chip.

17. The method of claim 16, wherein forming the first fan-out structure further comprises forming one or more redistribution layers (RDLs) on the logic chip, the molding compound, and the plurality of conductive pillars.

18. The method of claim 16 further comprising after bonding the one or more wide IO chips, bonding a package structure to a surface of the first fan-out structure opposing the one or more wide IO chips, wherein the package structure comprises:
a plurality of stacked dynamic random access memory (DRAM) chips;
a first package substrate electrically connected to the plurality of stacked DRAM chips; and
a plurality of connectors electrically connecting the first package substrate to the first fan-out structure, wherein the plurality of connectors is aligned with the plurality of conductive pillars.

19. The method of claim 16 further comprising bonding a second package substrate to the first fan-out structure, wherein the second package substrate comprises a through hole, and wherein bonding the one or more wide IO chips comprises disposing the one or more wide IO chips in the through hole.

20. The method of claim 16, wherein bonding the one or more wide IO chips comprises bonding a second fan-out structure comprising the one or more wide IO chips to the first fan-out structure.
